(19) United States
(12) Patent Application Publication
(10) Pub. No.: US 2025/0047055 A1
(43) Pub. Date: Feb. 6, 2025

(54) Frequency Stabilization Device and Atomic Clock Device

(71) Applicant: SHIMADZU CORPORATION, Kyoto-shi (JP)

(72) Inventor: Yusuke HISAI, Kyoto-shi (JP)

(21) Appl. No.: 18/770,556

(22) Filed: Jul. 11, 2024

(30) Foreign Application Priority Data
Jul. 12, 2023 (JP) 2023-114548

(51) Int. Cl. H01S 3/137; G04F 5/14; H01S 3/13

(52) U.S. Cl. CPC H01S 3/137; G04F 5/14; H01S 3/1305

(57) ABSTRACT

An electro-optic modulator that modulates a phase of laser beam with a modulation signal, an optical resonator that resonates laser beam modulated by the electro-optic modulator, and a servo circuit that adjusts a frequency of laser beam emitted by a laser device based on the optical resonator and the modulation signal are provided. The optical resonator resonates therein, laser beam at frequencies corresponding to a sideband in a frequency band of laser beam modulated by the electro-optic modulator.

### CROSS REFERENCE TO RELATED APPLICATIONS

This nonprovisional application is based on Japanese Patent Application No. 2023-114548 filed with the Japan Patent Office on Jul. 12, 2023, the entire contents of which are hereby incorporated by reference.

### BACKGROUND OF THE INVENTION

### Field of the Invention

The present disclosure relates to a frequency stabilization device that stabilizes a frequency of laser beam and an atomic clock device where laser beam emitted from the frequency stabilization device are used.

### Description of the Background Art

A Pound-Drever-Hall method is available as one of techniques to stabilize a frequency of laser beam. The PDH method is a technique to stabilize a frequency of laser beam with an optical resonator. In the PDH method, laser beam subjected to phase modulation at a frequency fₘ by an electro-optic modulator (EOM) are incident on the optical resonator. Light reflected from the optical resonator is taken out by a polarizing beam splitter (PBS) and received by a photodetector (photodiode). Then, a beat signal between carriers and a sideband is obtained. In the PDH method, the obtained beat signal is used as an error signal in feedback control, so that the frequency of laser beam can be stabilized at the frequency at which carriers resonate with the optical resonator.

### SUMMARY OF THE INVENTION

Stability of the frequency according to the PDH method is dependent on stability of a resonator length in the optical resonator. The resonator length is desirably as invariable as possible. One of factors for variation in resonator length is variation in quantity of light incident on the optical resonator. Light that is incident on the optical resonator and goes back and forth between a pair of mirrors heats the inside of the resonator and applies force to the mirrors in the optical resonator due to a radiation pressure. Light incident on the optical resonator produces thermal noise in the optical resonator, which also varies the stability of the frequency. Therefore, an intensity of a signal of light incident on the optical resonator is desirably low.

When the intensity of the signal of light incident on the optical resonator becomes low, on the other hand, intensity of coherent light of carriers and the sideband becomes low at the time of reception of laser beam in the photodetector, and an S/N ratio of the signal of light detected by the photodetector becomes low. Consequently, the stability of the frequency of laser beam deteriorates. In other words, there is such tradeoff that, as the quantity of light incident on the optical resonator is smaller, the resonator length in the optical resonator is more stable whereas the S/N ratio of the signal of light detected by the photodetector becomes lower.

The present disclosure was made to solve such a problem, and an object thereof is to suitably stabilize a frequency of laser beam.

The present disclosure relates to an atomic clock device. The atomic clock device includes a vacuum container, an atom generator that radiates atomic beam to the vacuum container, a first laser device that excites transition between energy levels of atoms by irradiation of the vacuum container with laser beam while the atom generator radiates atomic beam, a detection device that detects light intensity produced in proportion to an energy transition probability of atoms generated in the vacuum container, a controller that identifies a frequency of laser beam emitted by the first laser device based on the light intensity detected by the detection device, and a frequency stabilization device that stabilizes the frequency of laser beam emitted by the first laser device. The frequency stabilization device includes a phase modulation unit that modulates a phase of laser beam with a modulation signal, an optical resonance unit that resonates laser beam modulated by the phase modulation unit, and a laser adjustment unit that adjusts the frequency of laser beam emitted by the first laser device, based on the optical resonance unit and the modulation signal. The optical resonance unit resonates in the optical resonance unit, laser beam at frequencies corresponding to a sideband in a frequency band of laser beam modulated by the phase modulation unit.

The present disclosure relates to a frequency stabilization device that stabilizes a frequency of laser beam emitted by at least one laser device. The frequency stabilization device includes a phase modulation unit that modulates a phase of laser beam with a modulation signal, an optical resonance unit that resonates laser beam modulated by the phase modulation unit, and a laser adjustment unit that adjusts the frequency of laser beam emitted by the laser device, based on the optical resonance unit and the modulation signal. The optical resonance unit resonates in the optical resonance unit, laser beam at frequencies corresponding to a sideband in a frequency band of laser beam modulated by the phase modulation unit.

The foregoing and other objects, features, aspects and advantages of this invention will become more apparent from the following detailed description of this invention when taken in conjunction with the accompanying drawings.

### BRIEF DESCRIPTION OF THE DRAWINGS

FIG. 1 is a functional block diagram of an optical lattice atomic clock according to a first embodiment.

FIG. 2 is a conceptual diagram of optical lattices.

FIG. 3 is a functional block diagram of a frequency stabilization device according to the first embodiment.

FIG. 4 is a diagram for illustrating a frequency component of laser beam.

FIG. 5 shows a graph of simulation of an error signal.

FIG. 6 is a flowchart showing frequency stabilization processing in the frequency stabilization device.

FIG. 7 is a functional block diagram of a frequency stabilization device according to a second embodiment.

### DESCRIPTION OF THE PREFERRED EMBODIMENTS

The present embodiment will be described in detail with reference to the drawings. The same or corresponding elements in the drawings have the same reference characters allotted and description thereof will not be repeated in principle.

### First Embodiment

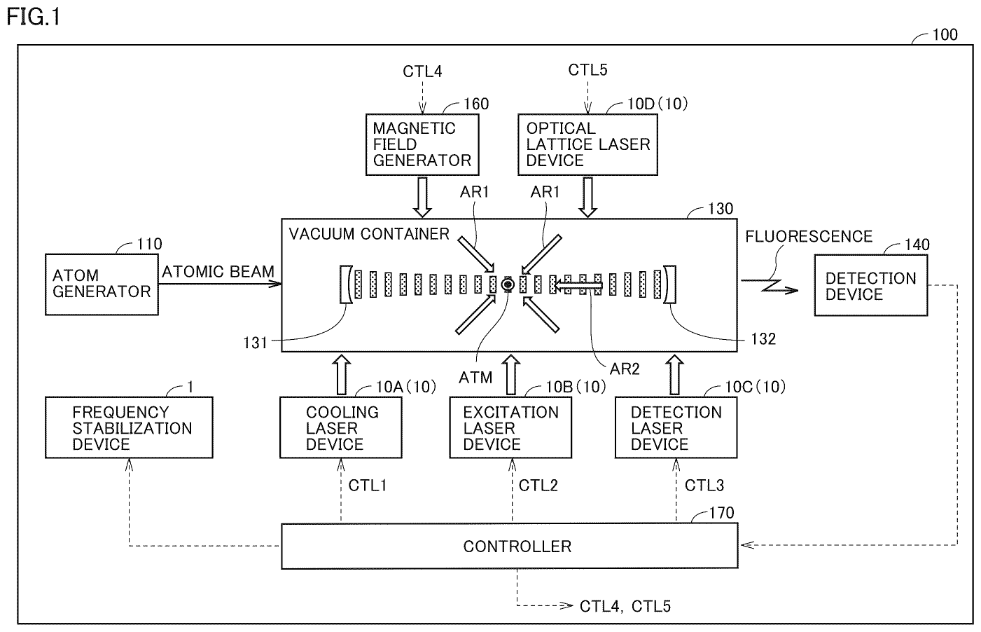

FIG. 1 is a functional block diagram of an atomic clock device 100 according to a first embodiment. Atomic clock device 100 in FIG. 1 is an optical lattice atomic clock (which is also referred to as an optical lattice clock).

Referring to FIG. 1, atomic clock device 100 includes an atom generator 110, a vacuum container 130, a detection device 140, a plurality of laser devices 10, a magnetic field generator 160, a controller 170, and a frequency stabilization device 1. The plurality of laser devices 10 include a cooling laser device 10A, an excitation laser device 10B, a detection laser device 10C, and an optical lattice laser device 10D.

Atom generator 110 includes a not-shown heating apparatus (oven), and heats in the oven, a base material for atoms of strontium, ytterbium, mercury, or the like. As a result of heating, chemical bond between atoms is cut, so that an atom is isolated and a group of atoms (atomic gas) is produced. Atoms gasified as a result of heating have high kinetic energy, and hence atomic gas at a high speed is radiated from atom generator 110 as atomic beam. Atomic beam radiated from atom generator 110 are guided into vacuum container 130.

Cooling laser device 10A is controlled by a control signal CTL1 from controller 170. Cooling laser device 10A emits in vacuum container 130, laser beams (shown with arrows AR1 and AR2 in FIG. 1) three-dimensionally opposed to atomic beam radiated from atom generator 110. These cooling laser beams are emitted in a direction opposite to a direction of motion of atomic beam, so that kinetic energy of atoms decreases (that is, atoms are cooled) and consequently the speed of atoms lowers.

A pair of opposing mirrors 131 and 132 is provided in vacuum container 130. When laser beam controlled to a specific wavelength (magic wavelength) by a control signal CTL5 from controller 170 is radiated from optical lattice laser device 10D in between these opposing mirrors 131 and 132, standing waves are produced between mirror 131 and mirror 132 by laser beam.

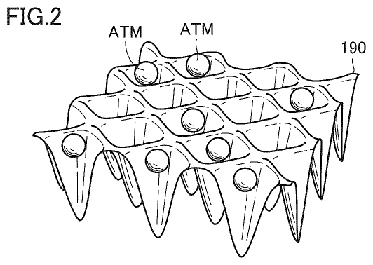

In general, atoms are polarized in electric field and produce an induced dipole. This dipole interacts with electric field. Consequently, in spatially non-uniform laser electric field, an electrical potential onto atoms attains to a relative minimum at a relative maximum point of an electric field intensity, and atoms are caught (trapped) at that position. When a standing wave of laser beam is produced between mirrors 131 and 132 as above, atoms are trapped at positions of antinodes of the standing waves. As the standing waves are three-dimensionally combined, “optical lattices” in which atoms are arranged at half-wavelength intervals are provided. FIG. 2 conceptually shows the optical lattices. Optical lattices 190 produced by laser in FIG. 2 are conceptually spatial interference fringes where recesses of the electrical potential are provided at regular intervals and atoms ATM are caught in the recesses.

As atoms have momentum (speed), a resonance frequency may be shifted owing to the Doppler effect and precision of counted time may lower. By reducing the speed of atoms ATM in atomic beam with laser beam from cooling laser device 10A and catching atoms ATM in optical lattices 190 as shown in FIG. 2, the resonance frequency of atoms in a stationary state can be searched for.

Magnetic field generator 160 is controlled by a control signal CTL4 from controller 170. Magnetic field generator 160 applies in vacuum container 130, magnetic field to atoms ATM in motion by feed of a current to an electromagnetic coil (not shown) arranged around mirrors 131 and 132. With this applied magnetic field, an energy level of atoms ATM is controlled, which contributes to various types of cooling of atoms.

Excitation laser device 10B is controlled by a control signal CTL2 from controller 170. Excitation laser device 10B emits pulsed laser beam to caught atoms ATM to excite energy transition of atoms ATM. Atoms generally have a plurality of intrinsic energy levels, and have such a property that photons at a frequency having energy comparable to a difference in energy level are selectively absorbed in transition between two different energy levels.

Detection laser device 10C is controlled by a control signal CTL3 from controller 170. Detection laser device 10C emits detection laser beam to atoms ATM after excitation of the energy level of atoms ATM by excitation laser device 10B. Laser emitted from detection laser device 10C generates fluorescence having intensity in proportion to an energy transition probability of atoms.

Detection device 140 receives fluorescence generated by detection laser device 10C and detects intensity of received fluorescence. Detection device 140 outputs to controller 170, a transition probability spectrum dependent on an excitation laser frequency represented by the detected intensity of fluorescence.

Controller 170 includes, for example, a central processing unit (CPU), a memory, and an input and output interface (none of which is shown), and controls each element in atomic clock device 100 in a centralized manner. Controller 170 identifies a resonance frequency of atoms ATM based on the transition probability spectrum received from detection device 140. In addition, controller 170 stabilizes the frequency of laser beam emitted from excitation laser device 10B based on the resonance frequency obtained by calculation.

Frequency stabilization device 1 is a device for stabilization of the frequency of laser beam emitted from laser device 10. In the first embodiment, stabilization of the frequency of laser beam emitted from excitation laser device 10B among a plurality of laser devices 10 will be described. Frequency stabilization device 1 may stabilize the frequency of laser beam emitted from laser device 10 other than excitation laser device 10B such as cooling laser device 10A, detection laser device 10C, and optical lattice laser device 10D, or may stabilize frequencies corresponding to a plurality of types of laser devices.

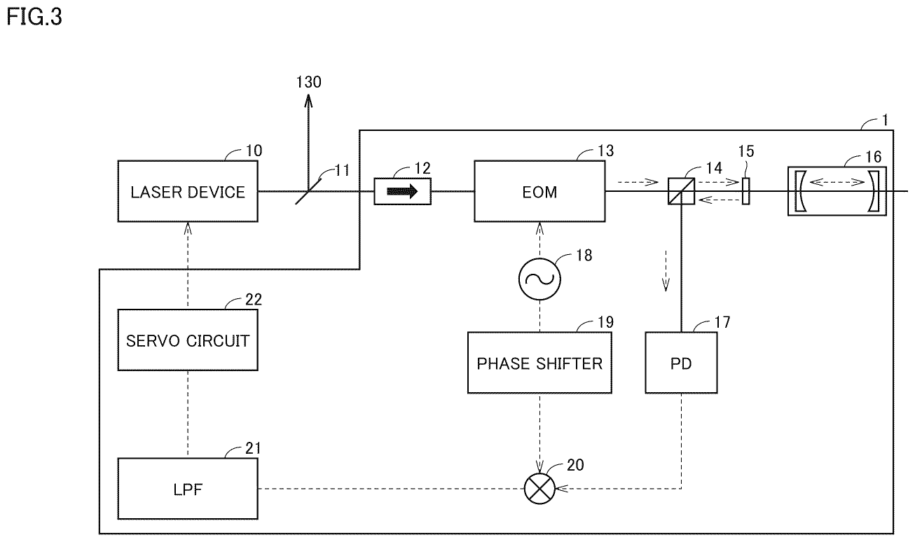

For atomic clock device 100 including such an optical lattice atomic clock, highly accurate stabilization of the frequency of laser beam is demanded. Frequency stabilization device 1 can suitably stabilize laser beam emitted, for example, from excitation laser device 10B among the plurality of laser devices 10. FIG. 3 is a functional block diagram of frequency stabilization device 1 according to the first embodiment.

Referring to FIG. 3, frequency stabilization device 1 includes an isolator 12, an electro-optic modulator (EOM) 13, a polarizing beam splitter (PBS) 14, a ¼ wave plate 15, an optical resonator 16, a photodiode (PD) 17, an RF oscillator 18, a phase shifter 19, a phase comparator 20, a low pass filter (LPF) 21, and a servo circuit 22.

Isolator 12 is provided in an optical path between laser device 10 and optical resonator 16. Isolator 12 is a device that transmits laser beam only in a certain direction. Being arranged around laser device 10, isolator 12 can prevent the frequency of laser beam derived from reflection light from becoming unstable. Electro-optic modulator 13 functions as a phase modulation unit that modulates a phase of laser beam. Electro-optic modulator 13 can electrically vary an index of refraction of light. Electro-optic modulator 13 modulates the frequency and the phase of laser beam based on a modulation signal inputted from RF oscillator 18.

Polarizing beam splitter 14 allows passage therethrough of some of incident laser beam and reflects laser beam that returns through ¼ wave plate 15 in a direction substantially at a right angle. Quarter wave plate 15 varies a state of polarization of laser beam incident from polarizing beam splitter 14 such that laser beam is incident on optical resonator 16, and varies again the state of polarization of laser beam that returns from optical resonator 16 such that laser beam returns to polarizing beam splitter 14.

Photodiode 17 functions as an optical detection unit that detects some of laser beam reflected by polarizing beam splitter 14 as a detection signal. Photodiode 17 outputs an electrical signal in accordance with intensity of laser beam. RF oscillator 18 functions as an oscillation unit that outputs a modulation signal. RF oscillator 18 outputs the modulation signal to electro-optic modulator 13 and phase shifter 19.

Phase shifter 19 shifts by 180 degrees, the phase of the modulation signal transmitted from RF oscillator 18. Phase comparator 20 functions as a phase comparison unit that calculates a comparison value obtained by comparison between the detection signal resulting from detection by photodiode 17 and the modulation signal from RF oscillator 18. Phase comparator 20 calculates an error from the detection signal and the modulation signal, with information on a difference between the frequency of optical resonator 16 and the frequency of laser beam being used as the comparison value. As the comparison value passes through low pass filter 21, an error signal based on the error is generated.

Servo circuit 22 functions as a laser adjustment unit that adjusts with the error signal, the frequency of laser beam emitted by laser device 10. Servo circuit 22 carries out feedback control such that the error becomes smaller, for example, by adjustment of the frequency of laser beam to a resonator length of optical resonator 16 in laser device 10.

Optical resonator 16 resonates laser beam modulated by electro-optic modulator 13. Optical resonator 16 includes a pair of mirrors therein for resonance of laser beam modulated by electro-optic modulator 13. Mirrors high in reflectivity (for example, around 99.9%) are adopted as the pair of mirrors such that light that leaks to the outside of optical resonator 16 is extremely weak. The number of mirrors arranged in the inside of optical resonator 16 is not limited to two, and three or more mirrors may be arranged. In other words, a resonator where mirrors are arranged such that light is reflected between/among them or a resonator where mirrors are arranged in a form of a ring such that light is reflected in one direction may be applicable.

A piezo element (piezoelectric element) is arranged in the mirror. The piezo element displaces the mirror included in optical resonator 16 in a direction of an optical axis by driving the mirror in accordance with a command from controller 170. The resonator length of optical resonator 16 can thus be varied. Therefore, the resonator length can be varied to be in conformity with a laser wave number, or the laser wave number can be swept to be in conformity with the resonator length.

A half mirror 11 is arranged between laser device 10 and isolator 12 of frequency stabilization device 1. Half mirror 11 allows passage therethrough of some of incident laser beam and reflects other incident laser beam in the direction substantially at the right angle. Half mirror 11 functions as a guide portion that guides some of stabilized laser beam into vacuum container 130 of atomic clock device 100.

Frequency stabilization device 1 is thus configured to stabilize the frequency of laser beam by causing laser beam modulated in phase to be incident on optical resonator 16, detecting laser beam outputted from optical resonator 16 with photodiode 17, and carrying out feedback based on detected laser beam. Since stability of the frequency by such a PDH method is dependent on the stability of the resonator length in the optical resonator, the resonator length is desirably as invariable as possible.

For example, light incident on the optical resonator produces thermal noise in the optical resonator, which also varies the stability of the frequency. Therefore, intensity of a signal of light incident on the optical resonator is desirably low. When the intensity of the signal of light incident on the optical resonator becomes low, on the other hand, intensity of coherent light of carriers and a sideband becomes low at the time of reception of laser beam in a photodetector, and an S/N ratio of the signal becomes low. Consequently, the stability of the frequency of laser beam deteriorates. In other words, there is such tradeoff that, as a quantity of light incident on the optical resonator is smaller, the resonator length in the optical resonator is more stable whereas the S/N ratio of the signal of light detected by the photodetector becomes lower.

As will be described below, frequency stabilization device 1 according to the embodiment is configured to use light corresponding to the sideband rather than light corresponding to carriers, as laser beam incident on optical resonator 16. Then, the optical resonance unit is configured to resonate laser beam at frequencies corresponding to the sideband in a frequency band of laser beam modulated by the phase modulation unit.

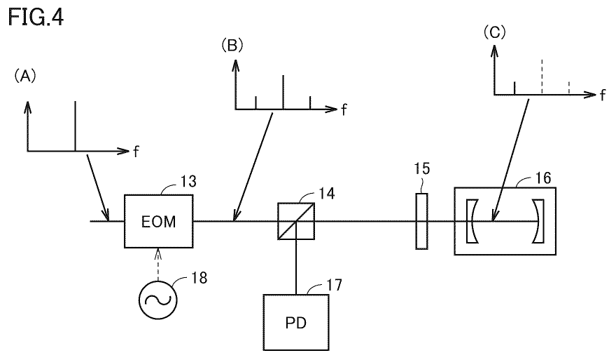

A frequency component of laser beam will specifically be described. FIG. 4 is a diagram for illustrating a frequency component of laser beam. Laser beam before it enters electro-optic modulator 13 is expressed as spectra where carriers exhibit a single peak as shown in FIG. 4 (A). Thereafter, RF oscillator 18 outputs to electro-optic modulator 13, the modulation signal with which laser beam at frequencies corresponding to the sideband can resonate in optical resonator 16. Laser beam modulated in phase in electro-optic modulator 13 is thus expressed as spectra having three peaks as shown in FIG. 4 (B). Peaks located on opposing sides of carriers in the center represent the sideband.

In optical resonator 16 in FIG. 4 (C), laser beam at the frequencies corresponding to the sideband in the frequency band of laser beam modulated by electro-optic modulator 13 is resonated. The present disclosure uses the sideband rather than carriers as laser beam to be resonated in optical resonator 16. For example, by adjustment of an oscillation frequency of laser device 10, the sideband is resonated in optical resonator 16. By setting the sideband lower in intensity of the signal than carriers as light incident on optical resonator 16, the resonator length in optical resonator 16 can be stabilized.

In photodiode 17, a beat signal between carriers and the sideband is obtained as in resonance of carriers in optical resonator 16. This is because intensity of coherent light can be secured owing to high signal intensity of carriers. The S/N ratio of the signal obtained by photodiode 17 can thus be prevented from lowering.

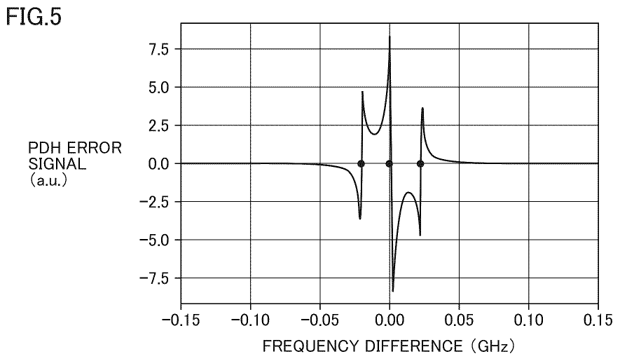

A problem in resonance of the sideband will now be described. FIG. 5 shows a graph of simulation of an error signal. In FIG. 5, simulation is made such that carriers coincide with the resonance frequency of optical resonator 16. In frequency stabilization processing, a point of zero crossing with a waveform of the error signal (the point where the error signal is zero) is a point of locking of the frequency used in optical resonator 16. As shown in FIG. 5, a point corresponding to carriers in the center among zero crossing points has a negative inclination. As shown in FIG. 5, points corresponding to the sideband on opposing sides of the point in the center among the zero crossing points have a positive inclination.

In other words, carriers and the sideband are opposite in inclination of the error signal. Therefore, when the sideband is used, phase shifter 19 should invert the phase by 180 degrees. Phase comparator 20 calculates a comparison value by comparing the detection signal from photodiode 17 with the modulation signal from RF oscillator 18 inverted in phase by 180 degrees. An appropriate error signal can thus be generated.

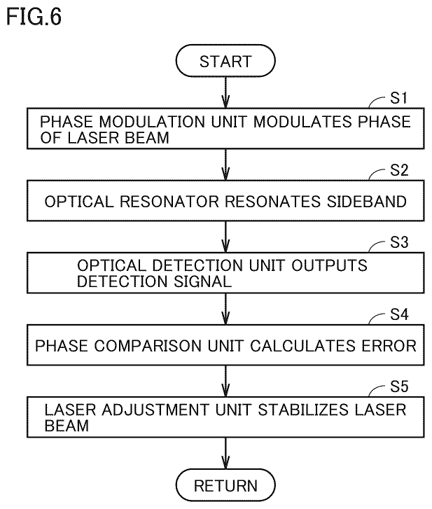

A flow of frequency stabilization processing performed in frequency stabilization device 1 will now be described. FIG. 6 is a flowchart showing the frequency stabilization processing in frequency stabilization device 1. Each step in the flowchart will simply be denoted as “S” below. Frequency stabilization device 1 modulates the phase of laser beam in electro-optic modulator 13 which is the phase modulation unit (S1). Frequency stabilization device 1 then resonates laser beam at the frequencies corresponding to the sideband in the frequency band of laser beam in optical resonator 16 (S2). Frequency stabilization device 1 then outputs the detection signal corresponding to the sideband obtained in photodiode 17 which is the optical detection unit (S3).

Frequency stabilization device 1 then calculates an error in phase comparator 20 which is the phase comparison unit, with the information on a difference between the frequency of optical resonator 16 and the frequency of laser beam being used as the comparison value (S4). Frequency stabilization device 1 then stabilizes laser beam in servo circuit 22 which is the laser adjustment unit (S5).

As a result of operations of frequency stabilization device 1 in accordance with the flow as above, laser beam at the frequencies corresponding to the sideband in the frequency band of laser beam modulated by electro-optic modulator 13 can resonate in optical resonator 16. By setting the sideband lower in signal intensity than carriers as light incident on optical resonator 16, the resonator length in optical resonator 16 can be stabilized. In addition, by detection of the beat signal between carriers and the sideband by photodiode 17, the S/N ratio of the signal obtained by photodiode 17 can be prevented from lowering.

### Second Embodiment

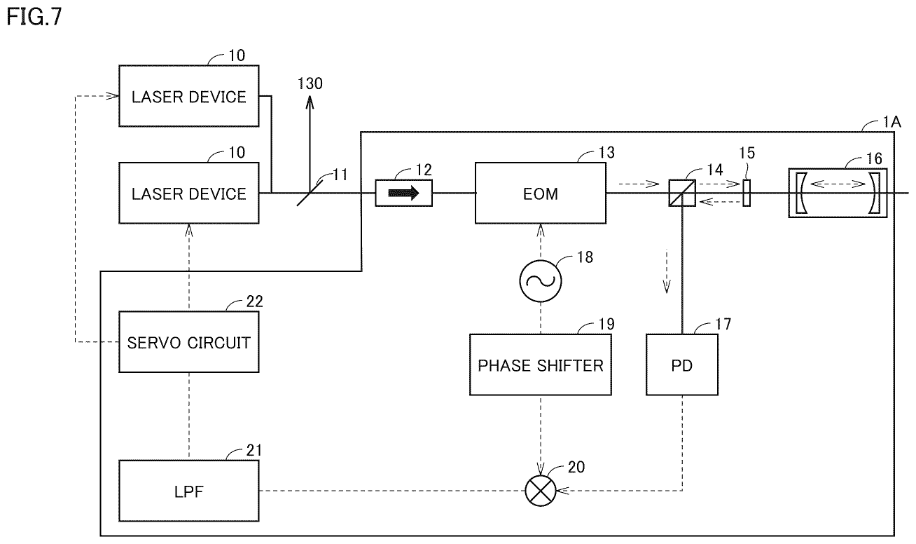

A frequency stabilization device 1A in a second embodiment will be described. FIG. 7 is a functional block diagram of frequency stabilization device 1A according to the second embodiment. Frequency stabilization device 1A in the second embodiment is the same in configuration as frequency stabilization device 1 in the first embodiment. The second embodiment is different from the first embodiment in that single laser device 10 is provided in the first embodiment whereas two laser devices 10 are provided in the second embodiment.

Frequency stabilization device 1A stabilizes frequencies of laser beams emitted from two laser devices among a plurality of laser devices 10. Frequency stabilization device 1A may stabilize frequencies of laser beams emitted from three or more laser devices.

Electro-optic modulator 13 of frequency stabilization device 1A can modulate frequencies and phases of a plurality of laser beams. For each of laser beams, optical resonator 16 resonate laser beam at frequencies corresponding to the sideband in the frequency band of laser beam modulated by electro-optic modulator 13. Thereafter, photodiode 17 detects, for each laser beam, the beat signal between carriers and the sideband. Though a plurality of laser beams are simultaneously incident on optical resonator 16, the resonator length is fixed to a constant value. This is because an oscillation frequency of laser beam emitted from each laser device 10 is adjusted to the resonance frequency of optical resonator 16 for resonance at the sideband.

Frequency stabilization device 1A resonates laser beam at the frequencies corresponding to the sideband among a plurality of laser beams. Thus, even when a plurality of laser beams are used, by setting the sideband lower in signal intensity than carriers as light incident on optical resonator 16, the resonator length in optical resonator 16 can be stabilized. By detection for each laser beam, of the beat signal between carriers and the sideband by photodiode 17, the S/N ratio of the signal obtained by photodiode 17 can be prevented from lowering.

### (Modification)

The embodiments above illustrate that the oscillation frequency of laser device 10 is varied and the resonator length of optical resonator 16 is set to be constant. The oscillation frequency of laser device 10, however, may be fixed and the resonator length of optical resonator 16 may be varied to a length corresponding to the frequencies corresponding to the sideband.

### <Application to Another Atomic Clock>

The embodiments above illustrate application of the technique to stabilize the frequency of laser beam in the optical lattice atomic clock. The concept of characteristics of the present disclosure, however, is also applicable to an atomic clock of a type other than the optical lattice atomic clock. For example, the technique to stabilize the frequency of laser beam may be applied to laser beam used in an atomic fountain microwave atomic clock, an atomic beam microwave atomic clock, or an optical ion clock.

### [Aspects]

Illustrative embodiments described above are understood by a person skilled in the art as specific examples of aspects below.

(Clause 1) An atomic clock device according to one aspect includes a vacuum container, an atom generator that radiates atomic beam to the vacuum container, a first laser device that excites transition between energy levels of atoms by irradiation of the vacuum container with laser beam while the atom generator radiates atomic beam, a detection device that detects light intensity produced in proportion to an energy transition probability of atoms generated in the vacuum container, a controller that identifies a frequency of laser beam emitted by the first laser device based on the light intensity detected by the detection device, and a frequency stabilization device that stabilizes the frequency of laser beam emitted by the first laser device. The frequency stabilization device includes a phase modulation unit that modulates a phase of laser beam with a modulation signal, an optical resonance unit that resonates laser beam modulated by the phase modulation unit, and a laser adjustment unit that adjusts the frequency of laser beam emitted by the first laser device, based on the optical resonance unit and the modulation signal. The optical resonance unit resonates in the optical resonance unit, laser beam at frequencies corresponding to a sideband in a frequency band of laser beam modulated by the phase modulation unit.

According to the atomic clock device described in Clause 1, when the frequency stabilization device stabilizes the frequency of laser beam emitted from the laser device, light corresponding to the sideband in the frequency band of laser beam modulated by the phase modulation unit can resonate in the optical resonance unit. By using light corresponding to the sideband lower in signal intensity than light corresponding to carriers as light incident on the optical resonance unit, a resonator length in the optical resonance unit can be stabilized. Even when light incident on the resonance unit is changed from light corresponding to carriers to light corresponding to the sideband, so long as signal intensity of one of carriers and the sideband is high, intensity of coherent light can be secured to some extent, and hence an S/N ratio of the signal can be prevented from lowering. Time can thus accurately be counted with the use of laser beam at the stable frequency.

(Clause 2) According to the atomic clock device described in Clause 1, the frequency stabilization device further includes an oscillation unit that outputs the modulation signal, an optical detection unit that detects as a detection signal, some of laser beam outputted from the optical resonance unit, and a phase comparison unit that calculates a comparison value obtained by comparison between the detection signal and the modulation signal. The laser adjustment unit adjusts the frequency of laser beam emitted by the first laser device, based on the comparison value.

According to the atomic clock device described in Clause 2, the frequency of laser beam emitted by the laser device can be adjusted based on the comparison value obtained by comparison between the detection signal and the modulation signal. The frequency of laser beam can thus suitably be stabilized.

(Clause 3) According to the atomic clock device described in Clause 1 or 2, the optical resonance unit is variable in resonator length, the resonator length being variable to a length corresponding to the frequencies corresponding to the sideband.

According to the atomic clock device described in Clause 3, the resonator length of the optical resonance unit is variable to the length corresponding to the frequencies corresponding to the sideband. The frequency of laser beam can thus suitably be stabilized.

(Clause 4) According to the atomic clock device described in any one of Clauses 1 to 3, the frequency stabilization device further includes a guide portion arranged between the first laser device and the phase modulation unit, the guide portion guiding some of laser beam emitted by the first laser device to the atomic clock device.

According to the atomic clock device described in Clause 4, the guide portion serves to send some of laser beam stabilized in frequency to the atomic clock device. Time can thus accurately be counted with the use of laser beam at the stable frequency.

(Clause 5) The atomic clock device described in any one of Clauses 1 to 4 further includes a second laser device. The first laser device emits first laser beam at a first wavelength and the second laser device emits second laser beam at a second wavelength. The frequency stabilization device stabilizes a frequency of each of first laser beam and second laser beam.

According to the atomic clock device described in Clause 5, the frequency of each of first laser beam and second laser beam can be stabilized.

(Clause 6) According to the atomic clock device described in any one of Clauses 2 to 5, the oscillation unit outputs to the phase modulation unit, the modulation signal with which laser beam at the frequencies corresponding to the sideband can resonate in the optical resonance unit.

According to the atomic clock device described in Clause 6, an appropriate modulation signal with which laser beam at the frequencies corresponding to the sideband can resonate in the optical resonance unit can be transmitted from the oscillation unit to the phase modulation unit. The frequency of laser beam can thus suitably be stabilized.

(Clause 7) According to the atomic clock device described in any one of Clauses 2 to 6, the phase comparison unit calculates the comparison value by comparing the detection signal with the modulation signal inverted in phase by 180 degrees.

According to the atomic clock device described in Clause 7, the comparison value corresponding to the sideband can be calculated. The frequency of laser beam can thus suitably be stabilized.

(Clause 8) A frequency stabilization device according to one aspect that stabilizes a frequency of laser beam emitted by at least one laser device includes a phase modulation unit that modulates a phase of laser beam with a modulation signal, an optical resonance unit that resonates laser beam modulated by the phase modulation unit, and a laser adjustment unit that adjusts the frequency of laser beam emitted by the laser device, based on the optical resonance unit and the modulation signal. The optical resonance unit resonates in the optical resonance unit, laser beam at frequencies corresponding to a sideband in a frequency band of laser beam modulated by the phase modulation unit.

According to the frequency stabilization device described in Clause 8, when the frequency stabilization device stabilizes the frequency of laser beam emitted from the laser device, light corresponding to the sideband in the frequency band of laser beam modulated by the phase modulation unit can resonate in the optical resonance unit.

By using light corresponding to the sideband lower in signal intensity than light corresponding to carriers as light incident on the optical resonance unit, a resonator length in the optical resonance unit can be stabilized. Even when light incident on the resonance unit is changed from light corresponding to carriers to light corresponding to the sideband, so long as signal intensity of one of carriers and the sideband is high, intensity of coherent light can be secured to some extent, and hence an S/N ratio of the signal can be prevented from lowering.

Though embodiments of the present invention have been described, it should be understood that the embodiments disclosed herein are illustrative and non-restrictive in every respect. The scope of the present invention is defined by the terms of the claims and is intended to include any modifications within the scope and meaning equivalent to the terms of the claims.

What is claimed is:

1. An atomic clock device comprising:
a vacuum container;
an atom generator that radiates atomic beam to the vacuum container;
a first laser device that excites transition between energy levels of atoms by irradiation of the vacuum container with laser beam while the atom generator radiates atomic beam;
a detection device that detects light intensity produced in proportion to an energy transition probability of atoms generated in the vacuum container;
a controller that identifies a frequency of laser beam emitted by the first laser device based on the light intensity detected by the detection device; and
a frequency stabilization device that stabilizes the frequency of laser beam emitted by the first laser device, wherein
the frequency stabilization device includes
a phase modulation unit that modulates a phase of laser beam with a modulation signal,
an optical resonance unit that resonates laser beam modulated by the phase modulation unit, and
a laser adjustment unit that adjusts the frequency of laser beam emitted by the first laser device, based on the optical resonance unit and the modulation signal, and
the optical resonance unit resonates in the optical resonance unit, laser beam at frequencies corresponding to a sideband in a frequency band of laser beam modulated by the phase modulation unit.

2. The atomic clock device according to claim 1, wherein
the frequency stabilization device further includes
an oscillation unit that outputs the modulation signal,
an optical detection unit that detects as a detection signal, some of laser beam outputted from the optical resonance unit, and
a phase comparison unit that calculates a comparison value obtained by comparison between the detection signal and the modulation signal, and
the laser adjustment unit adjusts the frequency of laser beam emitted by the first laser device, based on the comparison value.

3. The atomic clock device according to claim 1, wherein
the optical resonance unit is variable in resonator length, the resonator length being variable to a length corresponding to the frequencies corresponding to the sideband.

4. The atomic clock device according to claim 1, wherein
the frequency stabilization device further includes a guide portion arranged between the first laser device and the phase modulation unit, the guide portion guiding some of laser beam emitted by the first laser device to the atomic clock device.

5. The atomic clock device according to claim 1, further comprising a second laser device, wherein
the first laser device emits first laser beam at a first wavelength, and
the second laser device emits second laser beam at a second wavelength, and
the frequency stabilization device stabilizes a frequency of each of first laser beam and second laser beam.

6. The atomic clock device according to claim 2, wherein
the oscillation unit outputs to the phase modulation unit, the modulation signal with which laser beam at the frequencies corresponding to the sideband can resonate in the optical resonance unit.

7. The atomic clock device according to claim 2, wherein
the phase comparison unit calculates the comparison value by comparing the detection signal with the modulation signal inverted in phase by 180 degrees.

8. A frequency stabilization device that stabilizes a frequency of laser beam emitted by at least one laser device, the frequency stabilization device comprising:
a phase modulation unit that modulates a phase of laser beam with a modulation signal;
an optical resonance unit that resonates laser beam modulated by the phase modulation unit; and
a laser adjustment unit that adjusts the frequency of laser beam emitted by the laser device, based on the optical resonance unit and the modulation signal, wherein
the optical resonance unit resonates in the optical resonance unit, laser beam at frequencies corresponding to a sideband in a frequency band of laser beam modulated by the phase modulation unit.
